(19) United States
(12) Patent Application Publication
(10) Pub. No.: US 2026/0171698 A1
(43) Pub. Date: Jun. 18, 2026

(54) Server System Card Edge Connector System

(71) Applicant: Dell Products L.P., Round Rock, TX (US)

(72) Inventors: Charles Ziegler, East Providence, RI (US); Jason Pritchard, Hopkinton, MA (US)

(21) Appl. No.: 18/982,023

(22) Filed: Dec. 16, 2024

(51) Int. Cl. H01R 12/72; H01R 12/75; H05K 7/14

(52) U.S. Cl. CPC H01R 12/721; H01R 12/75; H05K 7/1491; H01R 2201/06

(57) ABSTRACT

A card edge connector system of an information handling system. The card edge connector system includes a cable; and, a connector interface component, the cable management component a circuit board, the circuit board includes a conductor projection and defining a connector recess, the conductor projection being located within the connector recess, the conductor projection comprising a plurality of conductors, the plurality of conductors being positioned to mate with a connector of a cable.

### BACKGROUND OF THE INVENTION

### FIELD OF THE INVENTION

The present invention relates to information handling systems. More specifically, embodiments of the invention relate to server type information handling systems within information technology (IT) environments.

### DESCRIPTION OF THE RELATED ART

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with cable management system, a card edge connector system, or a combination thereof.

In one embodiment, the invention relates to a connector interface component for a cable management system of an information handling system, comprising: a circuit board, the circuit board comprising a conductor projection and defining a connector recess, the conductor projection being located within the connector recess, the conductor projection comprising a plurality of conductors, the plurality of conductors being positioned to mate with a connector of a cable.

In another embodiment, the invention relates to a connector system of an information handling system comprising: a cable; and a circuit board, the circuit board comprising a conductor projection and defining a connector recess, the conductor projection being located within the connector recess, the conductor projection comprising a plurality of conductors, the plurality of conductors being positioned to mate with a connector of the cable.

In another embodiment, the invention relates to a system comprising: a chassis; a cable contained within the chassis; and a connector interface component contained within the chassis, the connector interface component comprising: a circuit board, the circuit board comprising a conductor projection and defining a connector recess, the conductor projection being located within the connector recess, the conductor projection comprising a plurality of conductors, the plurality of conductors being positioned to mate with a connector of the cable.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIG. 4 shows a top block diagram view of a cable management system.

FIGS. 5A, 5B and 5C, generally referred to as FIG. 5, show a plurality of views of a cable management system.

FIGS. 6A, 6B and 6C, generally referred to as FIG. 6, show diagrammatic block diagram views of a connector interface system.

FIG. 7 shows a top block diagram an alternate cable management system.

FIGS. 8A, 8B and 8C, generally referred to as FIG. 8, show a plurality of views of an alternate cable management system.

### DETAILED DESCRIPTION

Various aspects of the present disclosure include an appreciation that it is known to provide information handling systems with a plurality of components. Various aspects of the present disclosure include an appreciation that the plurality of components can include a plurality of printed circuit boards. Various aspects of the present disclosure include an appreciation that with certain known information handling systems each of the plurality of printed circuit boards is associated with respective power supply units.

Various aspects of the present disclosure include an appreciation that information handling systems often include cables which traverse the plurality of components. Various aspects of the present disclosure include an appreciation that cable management of the cables is an important aspect of information handling system design. Various aspects of the present disclosure include an appreciation that cable management can assist in protecting the cables from damage as well as ensuring that the cable is properly located and connected within the information handling system. Various aspects of the present disclosure include an appreciation that many known cable management methods generally require the addition of raw materials. Cable management is especially important in information handling systems configured for accelerator applications as there are typically many more internal cables relative to classic servers.

Information handling systems having faster speeds and bandwidth often results in a need for more cables due in part that cost effective circuit boards often contribute much more insertion loss relative to high-speed cables which can result in shorter cable reach. Various aspects of the present disclosure include an appreciation that with more and more cables in a system, it is desirable to provide a cost effective method for managing and holding cables without additional materials or components.

Various aspects of the present disclosure include an appreciation that it is known to use connectors to couple cables with components. Various aspects of the present disclosure include an appreciation that when latching a connector to a component, physical and electrical connection is typically achieved using a gold finger, type interface which is coupled via lever locks, screw locks, or spring-action type locks. Various aspects of the present disclosure include an appreciation that these connection methods often require additional materials and sometimes additional assembly steps to achieve a connector/component latch. Various aspects of the present disclosure include an appreciation that it would be desirable to reduce cost and streamline assembly while still firmly attaching a connector to a component such as a circuit board edge.

A system and method are disclosed for providing an information handling system with a cable system. In certain embodiments, the cable system includes a cable management system, a card edge connector system, or a combination thereof.

In certain embodiments, the cable management system includes cable management optimized components. In certain embodiments, the cable management optimized components include cable management optimized circuit boards. In certain embodiments, the cable management optimized circuit boards are configured with cable support braces. In certain embodiments, the cable support braces are positioned along an edge of the circuit board. In certain embodiments, the cable support braces are positioned close to respective cable connectors of the circuit board.

In certain embodiments, the cable support braces include one or more support notches, a support wall, or a combination thereof. In certain embodiments, the support notches hold an installed cable snugly within the cable support brace. In certain embodiments, the support notches are positioned to hold an installed cable against the support wall of the support brace. In certain embodiments, each support notch has an associated support projection. In certain embodiments, the support wall and the associated support projection define walls of the support notch. In certain embodiments, the cable support braces are v-grooved. In certain embodiments, the support braces are cut into an edge of the circuit board. In certain embodiments, the support braces are cut into an edge of the circuit board via a de-panelizing process.

In certain embodiments, the cable management system includes a plurality of vertically stacked circuit boards, each circuit board having an associated cable support brace. In certain embodiments, the associated cable support braces are arranged vertically relative to one another. In certain embodiments, the plurality of vertically arranged support braces facilitate vertical installation of a multi connector cable. In certain embodiments, the plurality of vertically stacked circuit boards each have a corresponding power supply unit.

Such a cable management system advantageously retains and manages a cable without requiring additional materials or components for an information handling system. Such a cable management system advantageously retains and manages a cable using circuit boards and connectors that would typically exist within the information handling system.

In certain embodiments, the card edge connector system includes a circuit board which defines a connector recess, a conductor projection located within the connector recess, a plurality of conductor positioned on at least one side of the conductor projection, a cable having an attached connector, or a combination thereof. In certain embodiments, the connector recess is defined by a first side connector flank, a second side connector flank or a combination thereof. In certain embodiments, the first side connector flank, the second side connector flank or a combination thereof, are cut into the circuit board. In certain embodiments, the first side connector flank, the second side connector flank or a combination thereof, provide a connector recess which is sized to hold the connector firmly when the connector is inserted into the connector recess to mate with the conductor projection. In certain embodiments, the first side connector flank, the second side connector flank or a combination thereof, include connector projections which are sized to provide a sideward force which holds the connector firmly when the connector is inserted into the connector recess to mate with the conductor projection.

In certain embodiments, the conductor projection includes a first side edge, a second side edge, or a combination thereof. In certain embodiments, the first side connector flank and the first side edge define a recess into which a first side of a connector housing of the connector fits. In certain embodiments, the second side connector flank and the second side edge define a recess into which a second side of a connector housing of the connector fits.

In certain embodiments, the plurality of conductors includes a plurality of conductive fingers. In certain embodiments, the plurality of conductive fingers are configured as trace edges on the circuit board. In certain embodiments, the plurality of conductors are positioned on a top surface of the conductor projection, a bottom surface of the conductor projection, or a combination thereof.

In certain embodiments, the connector includes a connector housing. In certain embodiments, the connector housing includes a first connector housing side, a second connector housing side, or a combination thereof. In certain embodiments, the first connector housing side, the second connector housing side, or a combination thereof, define indentations which mate with respective connector projections when the connector is inserted into the connector recess to mate with the conductor projection. In certain embodiments, the connector includes a first side recess, a second side recess, or a combination thereof. In certain embodiments, the first side recess, the second side recess, or a combination thereof define indentations which mate with respective connector projections when the connector is inserted into the connector recess to mate with the conductor projection.

Such a card edge connector system advantageously enables card edge connector latching without the added cost of a connector fastener or fastener receptacle or connector attachment lever. Such a card edge connector system advantageously simplifies connector assembly (e.g., because there is no need to screw down connectors) and mitigates cost of goods, as fewer components are necessary.

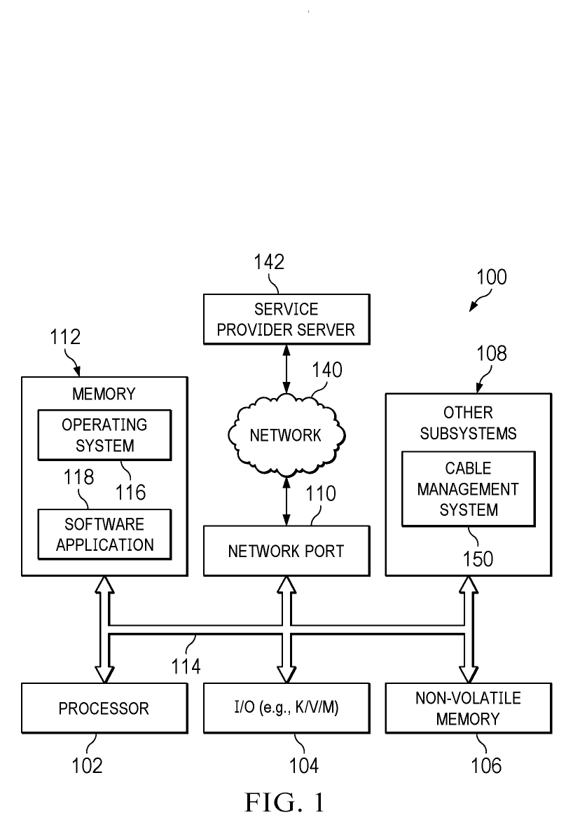

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a cable system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the cable system 150 includes a cable management system, a card edge connector system, or a combination thereof. In certain embodiments, the cable management system includes cable management optimized components. In certain embodiments, the cable management optimized components include cable management optimized circuit boards. In certain embodiments, the cable management optimized circuit boards are configured with cable support braces. In certain embodiments, the cable support braces are positioned along an edge of the circuit board. In certain embodiments, the cable support braces are positioned close to respective cable connectors of the circuit board.

In certain embodiments, the cable support braces include one or more support notches, a support wall, or a combination thereof. In certain embodiments, the support notches hold an installed cable snugly within the cable support brace. In certain embodiments, the support notches are positioned to hold an installed cable against the support wall of the support brace. In certain embodiments, each support notch has an associated support projection. In certain embodiments, the support wall and the associated support projection define walls of the support notch. In certain embodiments, the cable support braces are v-grooved. In certain embodiments, the support braces are cut into an edge of the circuit board. In certain embodiments, the support braces are cut into an edge of the circuit board via a de-panelizing process.

In certain embodiments, the cable management system includes a plurality of vertically stacked circuit boards, each circuit board having an associated cable support brace. In certain embodiments, the associated cable support braces are arranged vertically relative to one another. In certain embodiments, the plurality of vertically arranged support braces facilitate vertical installation of a multi connector cable. In certain embodiments, the plurality of vertically stacked circuit boards each have a corresponding power supply unit.

Such a cable management system advantageously retains and manages a cable without requiring additional materials or components for an information handling system. Such a cable management system advantageously retains and manages a cable using circuit boards and connectors that would typically exist within the information handling system.

In certain embodiments, the card edge connector system includes a circuit board which defines a connector recess, a conductor projection located within the connector recess, a plurality of conductor positioned on at least one side of the conductor projection, a cable having an attached connector, or a combination thereof. In certain embodiments, the connector recess is defined by a first side connector flank, a second side connector flank or a combination thereof. In certain embodiments, the first side connector flank, the second side connector flank or a combination thereof, are cut into the circuit board. In certain embodiments, the first side connector flank, the second side connector flank or a combination thereof, provide a connector recess which is sized to hold the connector firmly when the connector is inserted into the connector recess to mate with the conductor projection. In certain embodiments, the first side connector flank, the second side connector flank or a combination thereof, include connector projections which are sized to provide a sideward force which holds the connector firmly when the connector is inserted into the connector recess to mate with the conductor projection.

In certain embodiments, the conductor projection includes a first side edge, a second side edge, or a combination thereof. In certain embodiments, the first side connector flank and the first side edge define a recess into which a first side of a connector housing of the connector fits. In certain embodiments, the second side connector flank and the second side edge define a recess into which a second side of a connector housing of the connector fits.

In certain embodiments, the plurality of conductors includes a plurality of conductive fingers. In certain embodiments, the plurality of conductive fingers are configured as trace edges on the circuit board. In certain embodiments, the plurality of conductors are positioned on a top surface of the conductor projection, a bottom surface of the conductor projection, or a combination thereof.

In certain embodiments, the connector includes a connector housing. In certain embodiments, the connector housing includes a first connector housing side, a second connector housing side, or a combination thereof. In certain embodiments, the first connector housing side, the second connector housing side, or a combination thereof, define indentations which mate with respective connector projections when the connector is inserted into the connector recess to mate with the conductor projection. In certain embodiments, the connector includes a first side recess, a second side recess, or a combination thereof. In certain embodiments, the first side recess, the second side recess, or a combination thereof define indentations which mate with respective connector projections when the connector is inserted into the connector recess to mate with the conductor projection.

Such a card edge connector system advantageously enables card edge connector latching without the added cost of a connector fastener or fastener receptacle or connector attachment lever. Such a card edge connector system advantageously simplifies connector assembly (e.g., because there is no need to screw down connectors) and mitigates cost of goods as fewer components are necessary.

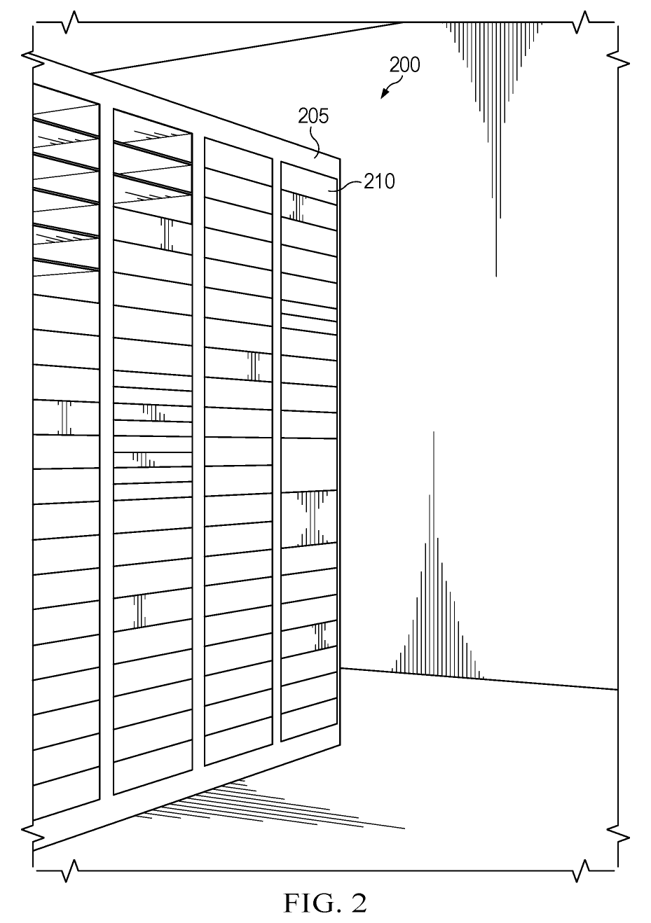

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/-20%) 1.75” high, a 2U rack unit is substantially (i.e., +/-20%) 3.5” high, and a 4U rack height is substantially (i.e., +/-20%) 7.0” high.

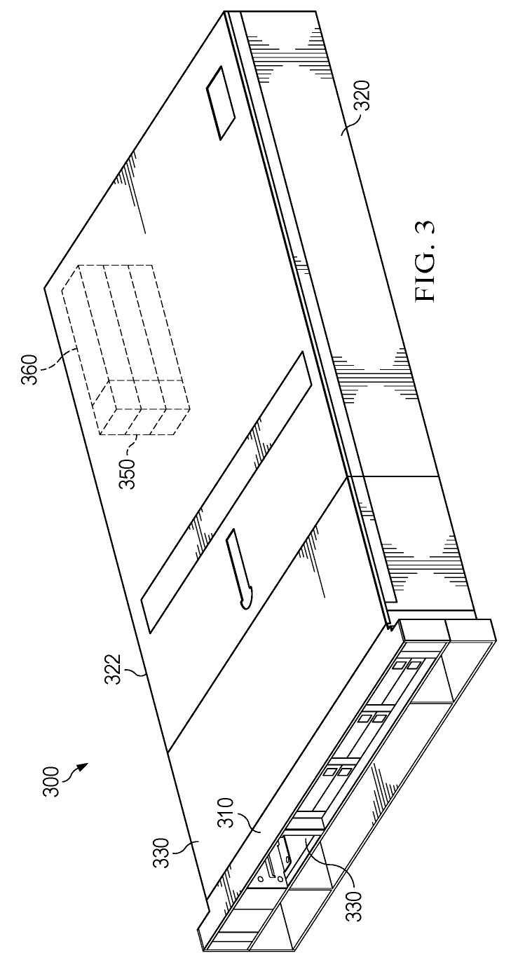

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 350 via which components may be mounted to the blade type information handling system.

In certain embodiments, the information handling system 300 includes a cable system 350, a power supply unit system 360, or a combination thereof.

In certain embodiments, the cable system 350 includes a cable management system, a card edge connector system, or a combination thereof. In certain embodiments, the cable management system includes cable management optimized components. In certain embodiments, the cable management optimized components include cable management optimized circuit boards. In certain embodiments, the cable management optimized circuit boards are configured with cable support braces. In certain embodiments, the cable support braces are positioned along an edge of the circuit board. In certain embodiments, the cable support braces are positioned close to respective cable connectors of the circuit board.

In certain embodiments, the cable support braces include one or more support notches, a support wall, or a combination thereof. In certain embodiments, the support notches hold an installed cable snugly within the cable support brace. In certain embodiments, the support notches are positioned to hold an installed cable against the support wall of the support brace. In certain embodiments, each support notch has an associated support projection. In certain embodiments, the support wall and the associated support projection define walls of the support notch. In certain embodiments, the cable support braces are v-grooved. In certain embodiments, the support braces are cut into an edge of the circuit board. In certain embodiments, the support braces are cut into an edge of the circuit board via a de-panelizing process.

In certain embodiments, the cable management system includes a plurality of vertically stacked circuit boards, each circuit board having an associated cable support brace. In certain embodiments, the associated cable support braces are arranged vertically relative to one another. In certain embodiments, the plurality of vertically arranged support braces facilitate vertical installation of a multi connector cable. In certain embodiments, the plurality of vertically stacked circuit boards each have a corresponding power supply unit from the power supply unit system 360.

Such a cable management system advantageously retains and manages a cable without requiring additional materials or components for an information handling system. Such a cable management system advantageously retains and manages a cable using circuit boards and connectors that would typically exist within the information handling system.

In certain embodiments, the card edge connector system includes a circuit board which defines a connector recess, a conductor projection located within the connector recess, a plurality of conductor positioned on at least one side of the conductor projection, a cable having an attached connector, or a combination thereof. In certain embodiments, the connector recess is defined by a first side connector flank, a second side connector flank or a combination thereof. In certain embodiments, the first side connector flank, the second side connector flank or a combination thereof, are cut into the circuit board. In certain embodiments, the first side connector flank, the second side connector flank or a combination thereof, provide a connector recess which is sized to hold the connector firmly when the connector is inserted into the connector recess to mate with the conductor projection. In certain embodiments, the first side connector flank, the second side connector flank or a combination thereof, include connector projections which are sized to provide a sideward force which holds the connector firmly when the connector is inserted into the connector recess to mate with the conductor projection.

In certain embodiments, the conductor projection includes a first side edge, a second side edge, or a combination thereof. In certain embodiments, the first side connector flank and the first side edge define a recess into which a first side of a connector housing of the connector fits. In certain embodiments, the second side connector flank and the second side edge define a recess into which a second side of a connector housing of the connector fits.

In certain embodiments, the plurality of conductors include a plurality of conductive fingers. In certain embodiments, the plurality of conductive fingers are configured as trace edges on the circuit board. In certain embodiments, the plurality of conductors are positioned on a top surface of the conductor projection, a bottom surface of the conductor projection, or a combination thereof.

In certain embodiments, the connector includes a connector housing. In certain embodiments, the connector housing includes a first connector housing side, a second connector housing side, or a combination thereof. In certain embodiments, the first connector housing side, the second connector housing side, or a combination thereof, define indentations which mate with respective connector projections when the connector is inserted into the connector recess to mate with the conductor projection. In certain embodiments, the connector includes a first side recess, a second side recess, or a combination thereof. In certain embodiments, the first side recess, the second side recess, or a combination thereof define indentations which mate with respective connector projections when the connector is inserted into the connector recess to mate with the conductor projection.

Such a card edge connector system advantageously enables card edge connector latching without the added cost of a connector fastener or fastener receptacle or connector attachment lever. Such a card edge connector system advantageously simplifies connector assembly (e.g., because there is no need to screw down connectors) and mitigates cost of goods as fewer components are necessary.

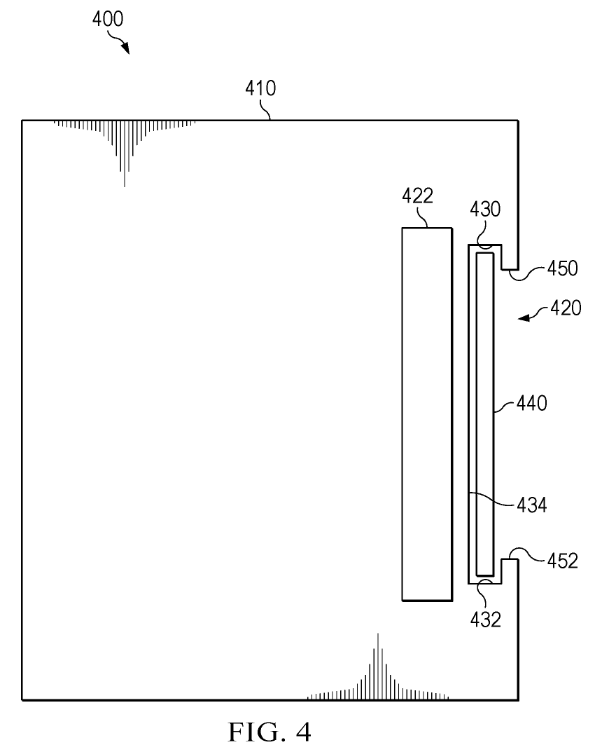

FIG. 4 shows a top block diagram view of a cable management system 400. In certain embodiments, the cable management system 400 corresponds to the cable management system of the cable system 150.

In certain embodiments, the cable management system 400 includes a cable management optimized component 410. In certain embodiments, the cable management optimized component 410 includes a cable management optimized circuit board. In certain embodiments, the cable management optimized circuit board is configured with a cable support brace 420. The cable support brace 420 comprises a laterally extending channel. In certain embodiments, the laterally extending channel is configured to support a cable. In certain embodiments, the cable support brace 420 is positioned along an edge of the circuit board 410. In certain embodiments, the cable support brace is positioned close to a respective cable connector 422 of the circuit board. In certain embodiments, the cable connector 422 extends substantially contiguously to the laterally extending channel.

In certain embodiments, the cable support brace 420 includes one or more support notches 430, 432, a support wall 434, or a combination thereof. In certain embodiments, the support notices 430, 432 are positioned along and define respective side portions of the laterally extending channel. In certain embodiments, the support wall 434 defines a rear portion of the laterally extending channel. In certain embodiments, the support notches 430, 432 hold an installed cable 440 snugly within the cable support brace 420. In certain embodiments, the installed cable 440 comprises a ribbon type cable. In certain embodiments, the support notches 430, 432 hold an installed cable 440 snugly within the laterally extending channel of the cable support brace 420. In certain embodiments, the support notches 430, 432 are positioned to hold the installed cable 440 snugly against the support wall 434 of the support brace. In certain embodiments, each support notch 430, 432 has an associated support projection 450, 452. In certain embodiments, the associated support projections 450, 452 define respective front portions of the laterally extending channel. In certain embodiments, portions of the support wall 434 and the associated support projections 450, 452 define walls of a respective support notch 430, 432. In certain embodiments, the cable support brace 420 is v-grooved. In certain embodiments, the support brace 420 is cut into an edge of the circuit board 410. In certain embodiments, the support brace 420 is cut into an edge of the circuit board via a de-panelizing process.

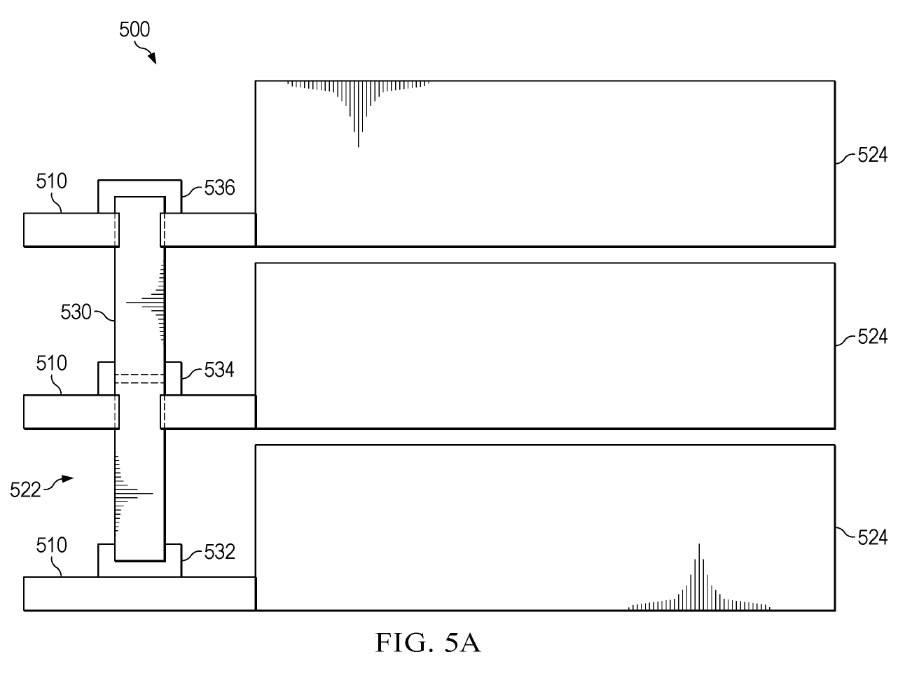

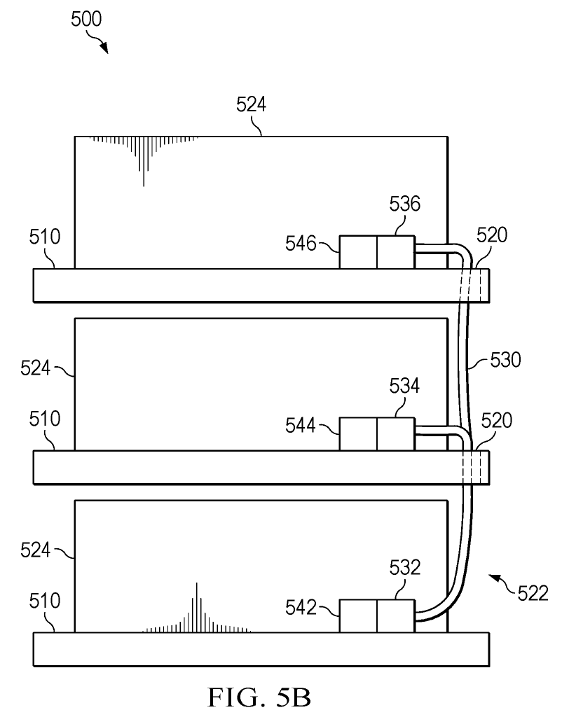

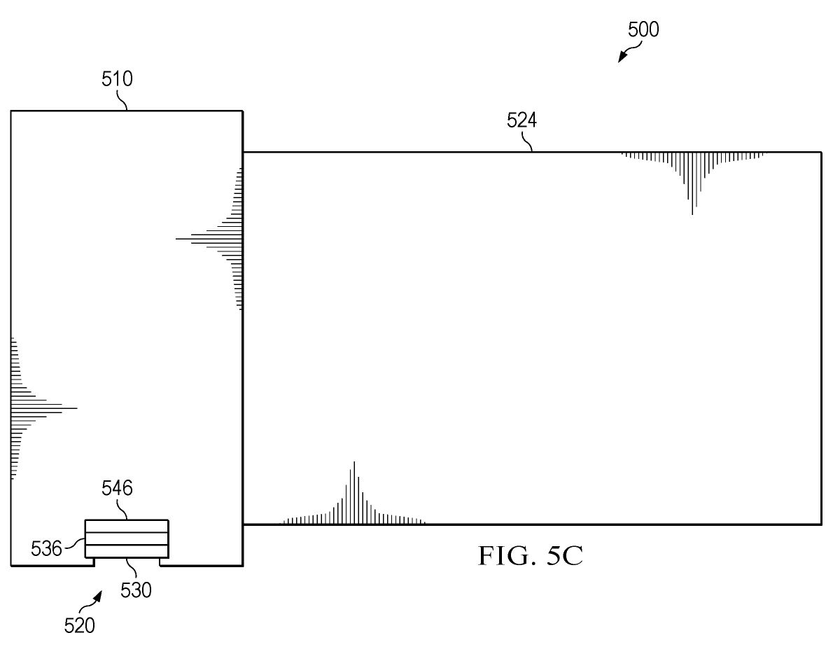

FIGS. 5A, 5B and 5C, generally referred to as FIG. 5, show a plurality of views of a cable management system. More specifically, FIG. 5A shows a side view of a cable management system 500. FIG. 5B shows a front view of a cable management system 500. FIG. 5C shows a top view of a cable management system 500. In certain embodiments, the cable management system 500 corresponds to the cable management system of the cable system 150.

In certain embodiments, the cable management system 500 includes a plurality of circuit boards 510 which are configured in a vertically stacked arrangement. In certain embodiments, one or more circuit boards 510 have an associated cable support brace 520. In certain embodiments, all of the virtually stacked circuit boards 510 have an associated support brace 520. In certain embodiments, middle and top circuit boards 510 have associated support braces while the bottom circuit board does not have an associated support brace. In certain embodiments, the associated cable support braces 520 are arranged vertically relative to one another. In certain embodiments, when the associated cable support braces 520 are arranged vertically relative to one another, the cable support braces are vertically aligned to support a vertical installation of a multi connector cable. In certain embodiments, the plurality of vertically arranged support braces 520 facilitate vertical installation of a multi connector cable 522. In certain embodiments, the multi connector cable 522 comprises a ribbon type cable. In certain embodiments, the plurality of vertically stacked circuit boards 510 each have a corresponding power supply unit 524 from a power supply unit system. In certain embodiments, the power supply unit system corresponds to power supply unit system 360.

In certain embodiments, the multi connector cable 522 includes a cable 530 and a plurality of connectors 532, 534, 536. In certain embodiments, the plurality of connectors 532, 534, 536 are physically and electrically coupled with a plurality of connectors 542, 544, 546 mounted on respective circuit boards 510.

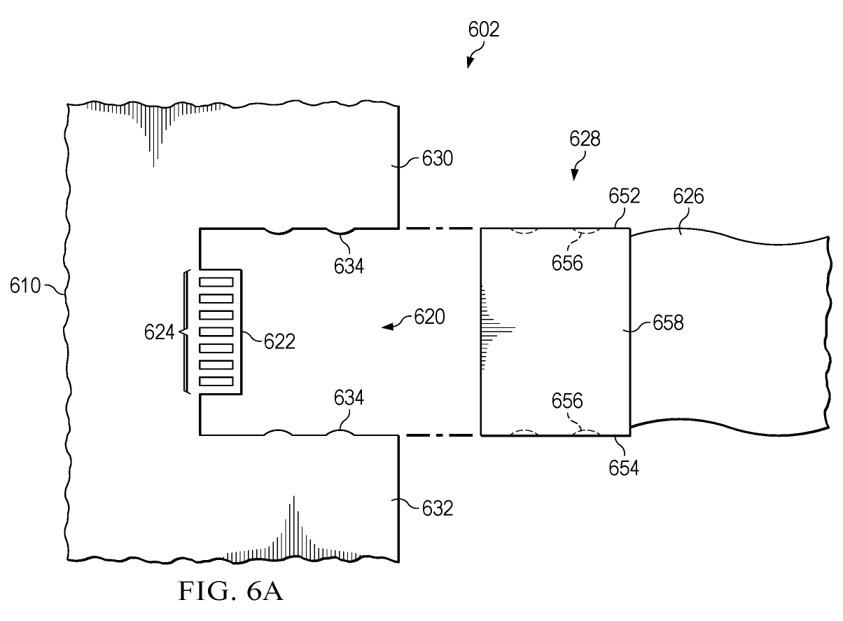

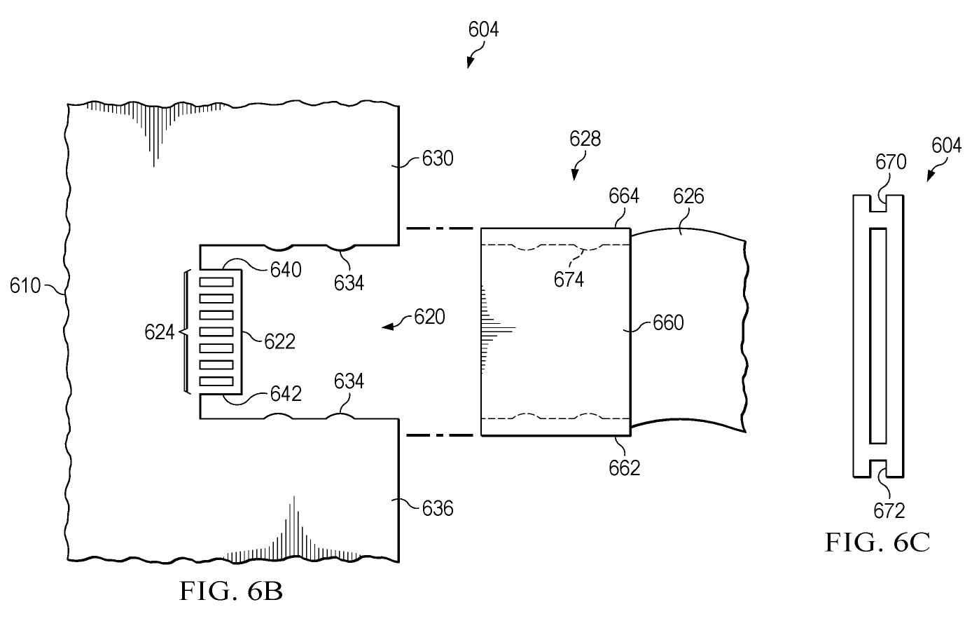

FIGS. 6A, 6B and 6C, generally referred to as FIG. 6, show diagrammatic block diagram views of a connector interface system. More specifically, FIG. 6A shows a diagrammatic block diagram top view of a connector interface system 602. FIG. 6B shows a diagrammatic block diagram top view of an alternate connector interface system 604. FIG. 6C shows a diagrammatic block diagram front view of an alternate connector interface system 604.

In certain embodiments, the card edge connector system 600 includes a circuit board 610 which defines a connector recess 620, a conductor projection 622 located within the connector recess, a plurality of conductors 624 positioned on at least one side of the conductor projection, a cable 626 having an attached connector 628, or a combination thereof. In certain embodiments, the connector recess 620 is positioned along an edge of the circuit board 610. In certain embodiments, the connector recess 620 is defined by a first side connector flank 630, a second side connector flank 632 or a combination thereof. In certain embodiments, the first side connector flank 630, the second side connector flank 632 or a combination thereof, are cut into the circuit board 610. In certain embodiments, the first side connector flank 630, the second side connector flank 632 or a combination thereof, provide a connector recess 620 which is sized to hold the connector 628 firmly when the connector is inserted into the connector recess to mate with the conductor projection. In certain embodiments, the first side connector flank 630, the second side connector flank 632 or a combination thereof, include connector projections 634 which are sized to provide a sideward force which holds the connector 620 firmly when the connector is inserted into the connector recess to mate with the conductor projection.

In certain embodiments, the conductor projection 622 is positioned to mate with the connector 628 of the cable 626. In certain embodiments, the plurality of conductors 624 are positioned to mate with the connector 628 of the cable 626. In certain embodiments, the conductor projection 622 is positioned along a rear wall of the connector recess 620. In certain embodiments, the conductor projection 622 includes a first side edge 640, a second side edge 642, or a combination thereof. In certain embodiments, the first side connector flank 630 and the first side edge 640 define a recess into which a first side of a connector housing of the connector fits. In certain embodiments, the second side connector flank 632 and the second side edge 642 define a recess into which a second side of a connector housing of the connector fits.

In certain embodiments, the plurality of conductors 624 include a plurality of conductive fingers. In certain embodiments, the plurality of conductive fingers are configured as trace edges on the circuit board. In certain embodiments, the plurality of conductors 624 are positioned on a top surface of the conductor projection, a bottom surface of the conductor projection, or a combination thereof.

In certain embodiments, the connector 628 includes a connector housing 650. In certain embodiments, the connector housing 650 includes a first connector housing side 652, a second connector housing side 654, or a combination thereof. In certain embodiments, the first connector housing side 652, the second connector housing side 654, or a combination thereof, define indentations 656 which mate with respective connector projections 634 when the connector is inserted into the connector recess to mate with the conductor projection 622.

Referring now to FIG. 6B and 6C, in certain embodiments, the connector 628 includes a connector housing 660. In certain embodiments, the connector housing 650 includes a first connector housing side 662, a second connector housing side 664, or a combination thereof. In certain embodiments, the connector 628 includes a first side recess 670, a second side recess 672, or a combination thereof. In certain embodiments, the first side recess 670 mates with an edge of the first side connector flank 630 when the connector is inserted into the connector recess to mate with the conductor projection. In certain embodiments, the second side recess 672 mates with an edge of the second side connector flank 632 when the connector is inserted into the connector recess to mate with the conductor projection. In certain embodiments, the first connector housing side 662, the second connector housing side 664, or a combination thereof, define indentations 674 which mate with respective connector projections 634 when the connector is inserted into the connector recess to mate with the conductor projection 622. In certain embodiments, an internal wall of the first side recess 670, an internal wall of the second side recess 672, or a combination thereof define indentations 674 which mate with respective connector projections when the connector is inserted into the connector recess to mate with the conductor projection 634.

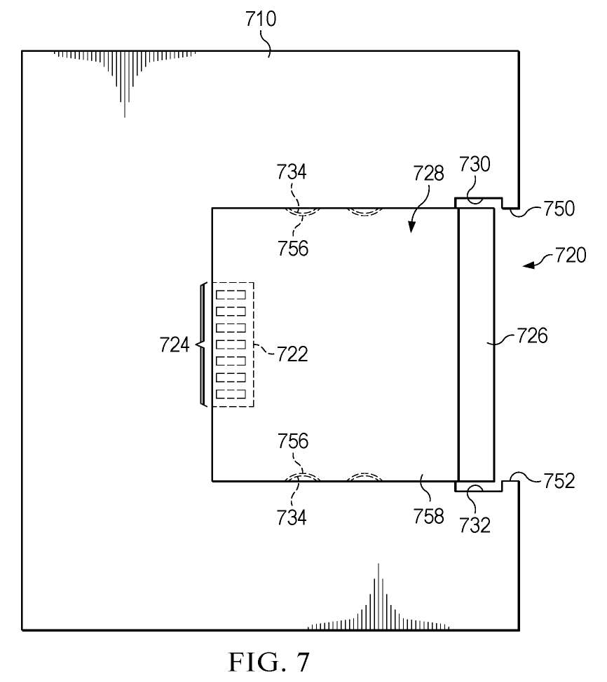

FIG. 7 shows a top block diagram an alternate cable system 700. In certain embodiments, the cable system 700 includes a cable management system 702 and a card edge connector system 702. In certain embodiments, the cable management system 702 corresponds to the cable management system of cable system 150. In certain embodiments, the card edge connector system 704 corresponds to the card edge connector system of cable system 150.

In certain embodiments, the cable management system 702 includes a cable management optimized component 710. In certain embodiments, the cable management optimized component 710 includes a cable management optimized circuit board. In certain embodiments, the cable management optimized circuit board is configured with a cable support brace 720. In certain embodiments, the cable support brace 720 is positioned along an edge of the circuit board 710. In certain embodiments, the cable support brace is positioned close to a respective cable connector 722 of the circuit board.

In certain embodiments, the cable support brace 720 includes one or more support notches 730, 732, a support wall 734, or a combination thereof. In certain embodiments, the support notches 730, 732 hold an installed cable 740 snugly within the cable support brace 720. In certain embodiments, the support notches 730, 732 are positioned to hold the installed cable 740 snugly against the support wall 734 of the support brace. In certain embodiments, each support notch 730, 732 has an associated support projection 750, 752. In certain embodiments, the support wall 734 and the associated support projections 750, 752 define walls of a respective support notch 730, 732. In certain embodiments, the cable support brace 720 is v-grooved. In certain embodiments, the support brace 720 is cut into an edge of the circuit board 710. In certain embodiments, the support brace 720 is cut into an edge of the circuit board via a de-panelizing process.

In certain embodiments, the card edge connector system 704 includes a circuit board 710 which defines a connector recess 720, a conductor projection 722 located within the connector recess, a plurality of conductors 724 positioned on at least one side of the conductor projection, a cable 726 having an attached connector 728, or a combination thereof. In certain embodiments, the connector recess 720 is defined by a first side connector flank 730, a second side connector flank 732 or a combination thereof. In certain embodiments, the first side connector flank 730, the second side connector flank 732 or a combination thereof, are cut into the circuit board 710. In certain embodiments, the first side connector flank 730, the second side connector flank 732 or a combination thereof, provide a connector recess 720 which is sized to hold the connector 728 firmly when the connector is inserted into the connector recess to mate with the conductor projection. In certain embodiments, the first side connector flank 730, the second side connector flank 732 or a combination thereof, include connector projections 734 which are sized to provide a sideward force which holds the connector 720 firmly when the connector is inserted into the connector recess to mate with the conductor projection.

In certain embodiments, the conductor projection 722 includes a first side edge 740, a second side edge 742, or a combination thereof. In certain embodiments, the first side connector flank 730 and the first side edge 740 define a recess into which a first side of a connector housing of the connector fits. In certain embodiments, the second side connector flank 732 and the second side edge 742 define a recess into which a second side of a connector housing of the connector fits.

In certain embodiments, the plurality of conductors 724 includes a plurality of conductive fingers. In certain embodiments, the plurality of conductive fingers are configured as trace edges on the circuit board. In certain embodiments, the plurality of conductors 724 are positioned on a top surface of the conductor projection, a bottom surface of the conductor projection, or a combination thereof.

In certain embodiments, the connector 728 includes a connector housing 750. In certain embodiments, the connector housing 750 includes a first connector housing side 752, a second connector housing side 754, or a combination thereof. In certain embodiments, the first connector housing side 752, the second connector housing side 754, or a combination thereof, define indentations 756 which mate with respective connector projections 734 when the connector is inserted into the connector recess to mate with the conductor projection 722.

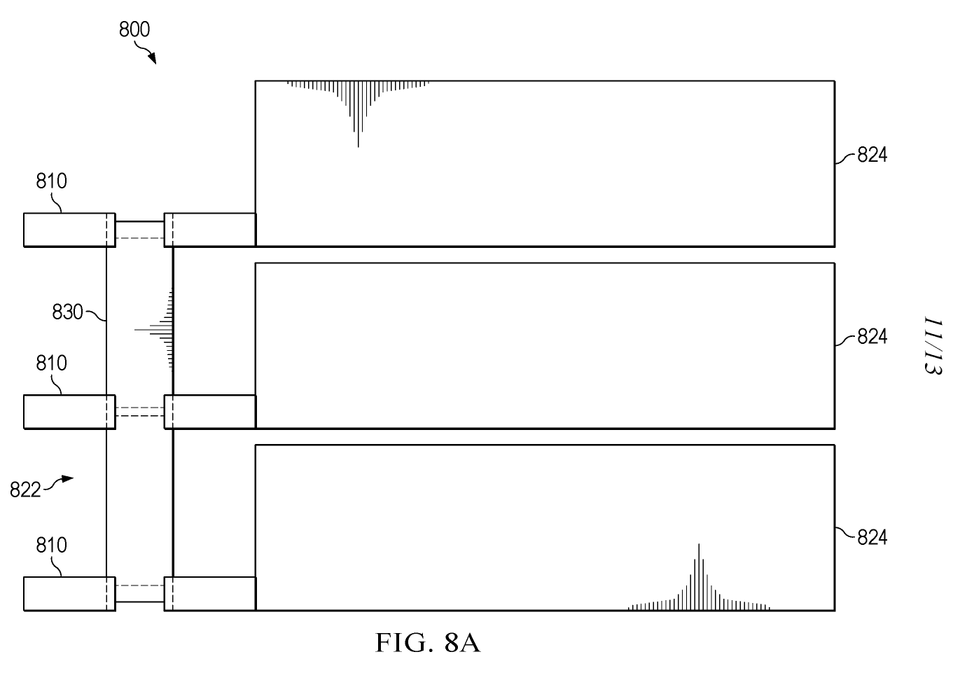

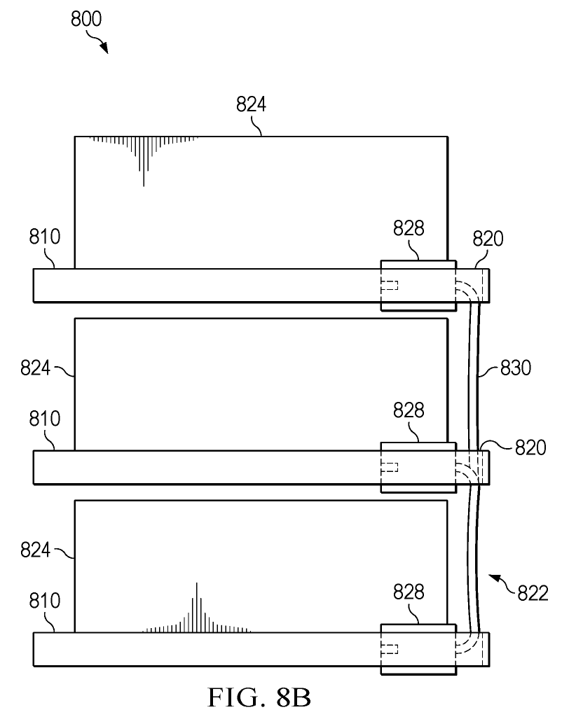

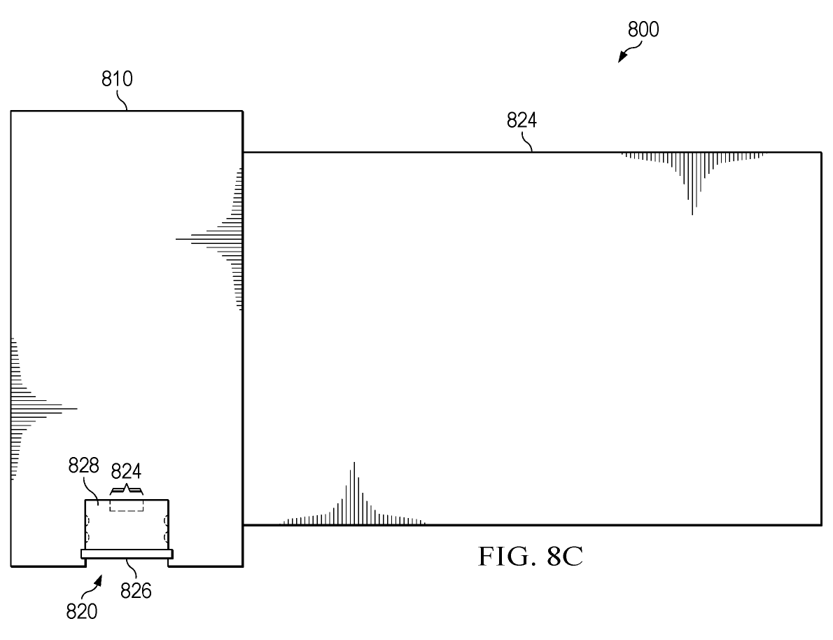

FIGS. 8A, 8B and 8C, generally referred to as FIG. 8, show a plurality of views of an alternate cable management system. More specifically, FIG. 8A shows a side view of a cable management system 800. FIG. 8B shows a front view of a cable management system 800. FIG. 8C shows a top view of a cable management system 800. In certain embodiments, the cable management system 800 corresponds to the cable management system of the cable system 150.

In certain embodiments, the cable management system 800 includes a plurality of vertically stacked circuit boards 810, one or more circuit boards 810 has an associated cable support brace 820. In certain embodiments, all of the virtually stacked circuit boards 810 have an associated support brace 820. In certain embodiments, middle and top circuit boards 810 have associated support braces while the bottom circuit board does not have an associated support brace. In certain embodiments, the associated cable support braces 820 are arranged vertically relative to one another. In certain embodiments, the plurality of vertically arranged support braces 820 facilitate vertical installation of a multi connector cable 822. In certain embodiments, the plurality of vertically stacked circuit boards 810 each have a corresponding power supply unit 824 from a power supply unit system. In certain embodiments, the power supply unit system corresponds to power supply unit system 360.

In certain embodiments, the multi connector cable 822 includes a cable 830 and a plurality of connectors 832, 834, 836. In certain embodiments, the plurality of connectors 832, 834, 836 are physically and electrically coupled with conductor projections 842, 844, 846 extending from connector recesses of respective circuit boards 810.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A connector interface component for a connector system of an information handling system, comprising:
a circuit board, the circuit board comprising a conductor projection and defining a connector recess, the conductor projection being located within the connector recess, the conductor projection comprising a plurality of conductors, the plurality of conductors being positioned to mate with a connector of a cable.

2. The connector interface component of claim 1, wherein:
the connector recess is positioned along an edge of the circuit board.

3. The connector interface component of claim 1, wherein:
the circuit board comprises a first side flank and a second side flank, the first side flank and the second side flank being configured to size the connector recess to hold the connector firmly when the connector is inserted to mate with the conductor projection.

4. The connector interface component of claim 3, wherein:
at least one of the first side flank and the second side flank comprise a connector projection, the connector projection being sized to provide a sideward force to hold the connector firmly when the connector is inserted into the connector recess to mate with the conductor projection.

5. The connector interface component of claim 4, wherein:
the connector comprises a connector housing, the connector housing defining an indentation, the indentation being positioned to mate with the connector projection when the connector is inserted into the connector recess to mate with the conductor projection.

6. The connector interface component of claim 5, wherein:
the connector housing includes a connector housing side, the housing side portion defining a side recess, the side recess mating with at least one of the first side flank and the second side flank when the connector is inserted into the connector recess to mate with the conductor projection.

7. A connector system of an information handling system comprising:
a cable; and,
a connector interface component, the connector interface component comprising
a circuit board, the circuit board comprising a conductor projection and defining a connector recess, the conductor projection being located within the connector recess, the conductor projection comprising a plurality of conductors, the plurality of conductors being positioned to mate with a connector of a cable.

8. The connector system of claim 7, wherein:
the connector recess is positioned along an edge of the circuit board.

9. The connector system of claim 7, wherein:
the circuit board comprises a first side flank and a second side flank, the first side flank and the second side flank being configured to size the connector recess to hold the connector firmly when the connector is inserted to mate with the conductor projection.

10. The connector system of claim 9, wherein:
at least one of the first side flank and the second side flank comprise a connector projection, the connector projection being sized to provide a sideward force to hold the connector firmly when the connector is inserted into the connector recess to mate with the conductor projection.

11. The connector system of claim 10, wherein:
the connector comprises a connector housing, the connector housing defining an indentation, the indentation being positioned to mate with the connector projection when the connector is inserted into the connector recess to mate with the conductor projection.

12. The connector system of claim 11, wherein:
the connector housing includes a connector housing side, the housing side portion defining a side recess, the side recess mating with at least one of the first side flank and the second side flank when the connector is inserted into the connector recess to mate with the conductor projection.

13. A system comprising:
a chassis;
a cable contained within the chassis; and,
a connector system contained within the chassis, the connector system comprising
a circuit board, the circuit board comprising a conductor projection and defining a connector recess, the conductor projection being located within the connector recess, the conductor projection comprising a plurality of conductors, the plurality of conductors being positioned to mate with a connector of a cable.

14. The system of claim 13, wherein:
the connector recess is positioned along an edge of the circuit board.

15. The system of claim 13, wherein:
the circuit board comprises a first side flank and a second side flank, the first side flank and the second side flank being configured to size the connector recess to hold the connector firmly when the connector is inserted to mate with the conductor projection.

16. The system of claim 15, wherein:
at least one of the first side flank and the second side flank comprise a connector projection, the connector projection being sized to provide a sideward force to hold the connector firmly when the connector is inserted into the connector recess to mate with the conductor projection.

17. The system of claim 16, wherein:
the connector comprises a connector housing, the connector housing defining an indentation, the indentation being positioned to mate with the connector projection when the connector is inserted into the connector recess to mate with the conductor projection.

18. The system of claim 17, wherein:
the connector housing includes a connector housing side, the housing side portion defining a side recess, the side recess mating with at least one of the first side flank and the second side flank when the connector is inserted into the connector recess to mate with the conductor projection.
